(19) United States
(12) Patent Application Publication
(10) Pub. No.: US 2014/0002986 A1
(43) Pub. Date: Jan. 2, 2014

(54) ELECTRONIC DEVICE INCORPORATING FAN MODULE

(71) Applicant: ZHI-BIN GUAN, Tu-Cheng (TW)

(72) Inventor: ZHI-BIN GUAN, Tu-Cheng (TW)

(73) Assignee: HON HAI PRECISION INDUSTRY CO., LTD., Tu-Cheng (TW)

(21) Appl. No.: 13/558,365

(22) Filed: Jul. 26, 2012

(30) Foreign Application Priority Data
Jun. 27, 2012 (CN) 2012102150803

(51) Int. Cl. H05K 7/20; G06F 1/20

(52) U.S. Cl. 361/679.48; 361/695

(57) ABSTRACT

An electronic device includes a chassis and a fan module received in the chassis. The chassis includes a bottom wall, a sidewall extending from a side of the bottom wall, and a cover fixed to the sidewall and spaced from the bottom wall. The fan module includes a bracket for receiving a number of fans, a number of parallel slide rails mounted on a top of the bracket, and a number of blocking plates each slidably received in two adjacent slide rails and covering the corresponding fan. To access the fans, the blocking plates are slid to be located under the cover, to expose the fans.

### BACKGROUND

1. Technical Field

The present disclosure relates to an electronic device including a fan module.

2. Description of Related Art

An electronic device often uses a plurality of fans for heat dissipation. The fans are installed in a chassis of the electronic device. However, should a fan need to be repaired or replaced, the cover of the chassis must be removed, which is inconvenient.

### BRIEF DESCRIPTION OF THE DRAWINGS

Many aspects of the present embodiments can be better understood with reference to the following drawings. The components in the drawing are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an electronic device in accordance with an exemplary embodiment.

FIG. 2 is an enlarged view of a circled portion II of FIG. 1.

FIG. 3 is an assembled view of FIG. 1.

FIG. 4 is a using state view of the electronic device of FIG. 3.

### DETAILED DESCRIPTION

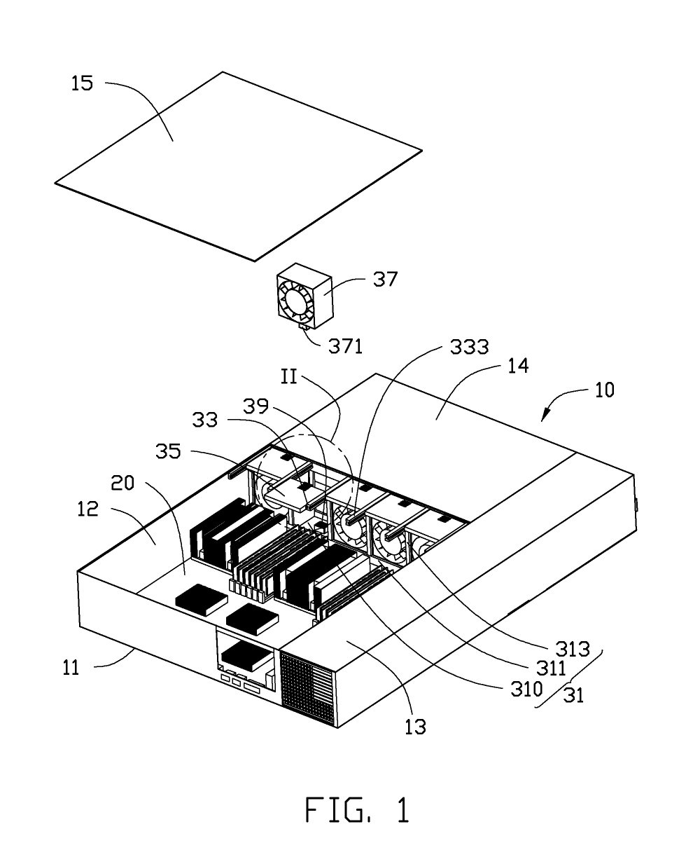

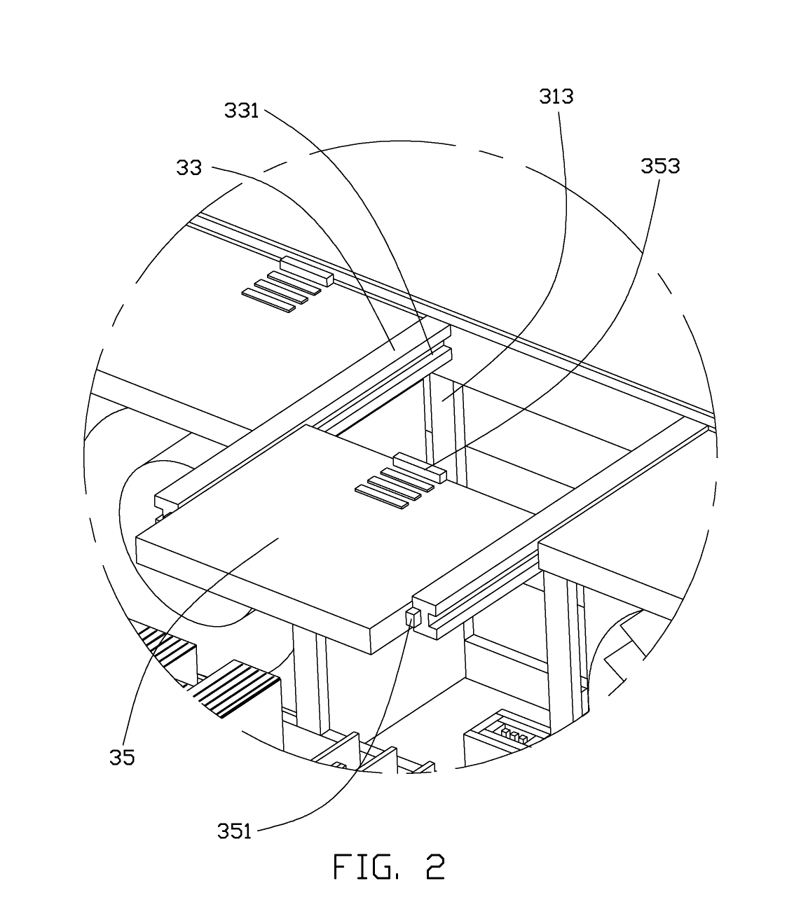

Referring to FIG. 1 and FIG. 2, an embodiment of an electronic device includes a chassis 10, a motherboard 20 fixed in the chassis 10, and a fan module 30 fixed in the chassis 10 and located adjacent to the motherboard 20.

The chassis 10 includes a bottom wall 11, a sidewall 12 extending from a first side of the bottom wall 11, a power unit 13 arranged on a second side of the bottom wall 11 opposite to the sidewall 12, and a cover 15. The motherboard 20 is supported on the bottom wall 11. A function module area 14, for receiving function modules such as data storage devices, is arranged on the bottom wall 11 opposite to the motherboard 20. The fan module 30 is set on the bottom wall 11 between the motherboard 20 and the function module area 14. The cover 15 covers the chassis 10 and is located between the sidewall 12 and the power unit 13, above the motherboard 20.

The fan module 30 includes a bracket 31 mounted on the bottom wall 11 between the motherboard 20 and the function module area 14, a plurality of slide rails 33 set on a top portion of the bracket 31 and parallel to the sidewall 12, a plurality of blocking plates 35 each slidably mounted between two adjacent slide rails 33, and a plurality of fans 37 each located below one of the blocking plates 35. The bracket 31 includes a bottom plate 310 fixed on the bottom wall 11, two parallel flanges 311 extending from opposite sides of the bottom plate 310 perpendicular to the sidewall 12, and a plurality of pairs of bars 313 extending up perpendicularly from the flanges 311. A plurality of connectors 39 electrically connected to the motherboard 20 is arranged on the bottom plate 310, corresponding to the fans 37 respectively. Two adjacent pairs of bars 313 form a space to receive one of the fans 37. One of the slide rails 33 is positioned on top portions of each pair of bars 313. Each slide rail 33 has a substantially H-shaped cross-section. Two slide slots 331 are defined in opposite sides of each slide rail 33. Each slide rail 33 includes a cantilever 333 extending above the motherboard 20. Each blocking plate 35 includes two edges 351 slidably received in the slide slots 331 of two adjacent slide rails 33. An operation portion 353 is formed on a top of each blocking plate 35. Each fan 37 includes a fan connector 371 extending from a bottom of the fan 37.

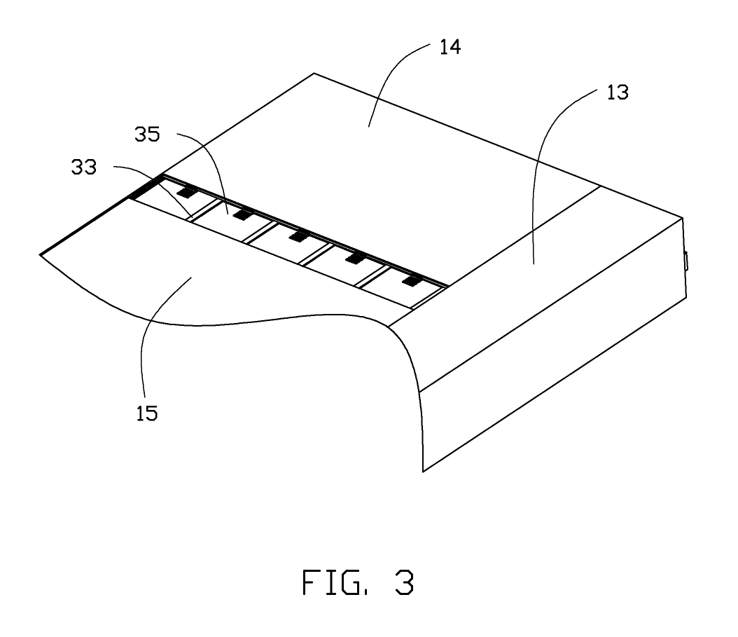

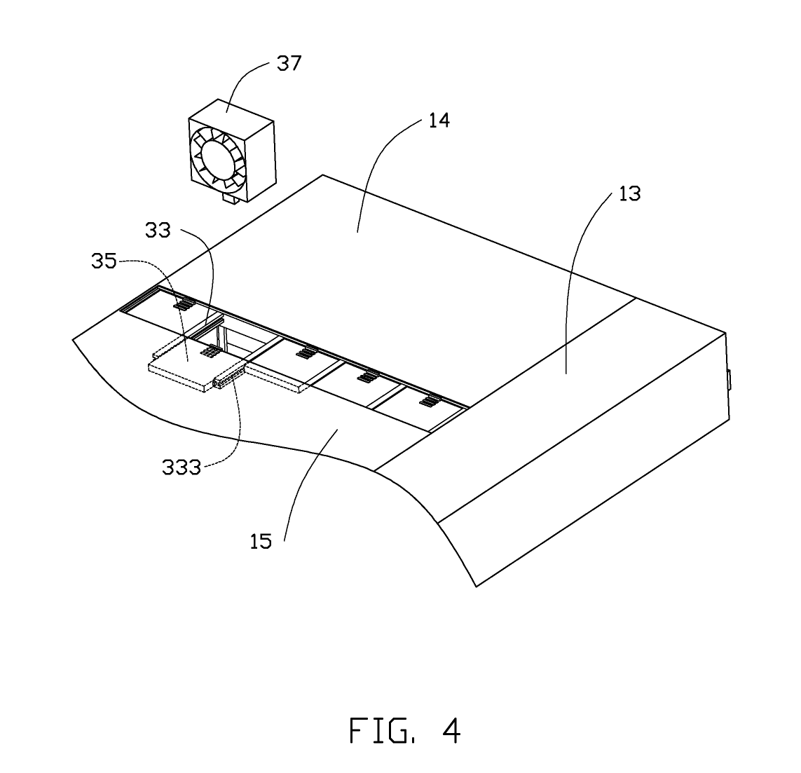

Shown in FIG. 3 and FIG. 4, in assembly, the cover 15 is mounted on the chassis 10. The cantilevers 333 are covered by the cover 15. The blocking plates 35 are exposed between the cover 15 and the function module area 14. To assemble one of the fans 37, the operation portion 353 of the corresponding blocking plate 35 is operated to slide the blocking plate 35 toward the cover 15, until the blocking plate 35 is located under the cover 15. The operation portion 353 is blocked by an edge of the cover 15 adjacent to the function module area 14, for preventing the blocking plate 15 from further sliding. The fan 37 is received in the bracket 31, with the fan connector 371 inserted into the corresponding connector 39. The blocking plate 35 is then slid back to cover the fan 37. To repair one of the fans 37, the operation portion 353 of the corresponding blocking plate 35 is operated to slide the blocking plate 35 toward the cover 15, until the blocking plate 35 is located under the cover 15 to expose the fan 37.

Even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An electronic device, comprising:
a chassis comprising a bottom wall, a sidewall extending from a first side of the bottom wall, and a cover mounted to a top portion of the sidewall and located above the bottom wall; and
a fan module supported on the bottom wall, and comprising a bracket mounted on the bottom wall and receiving a plurality of fans, a plurality of slide rails mounted on a top portion of the bracket, and a plurality of blocking plates each slidably mounted between two adjacent slide rails for covering or uncovering a corresponding one of the fans, wherein each blocking plate is exposed outside.

2. The electronic device as claimed in claim 1, wherein two slide slots are defined in opposite sides of each slide rail, each blocking plate comprises two edges respectively received in two opposite slide slots of two adjacent slide rails.

3. The electronic device as claimed in claim 1, wherein each slide rail comprises a cantilever extending below the cover.

4. The electronic device as claimed in claim 1, wherein an operation portion is formed on a top of each blocking plate.

5. The electronic device as claimed in claim 1, wherein the bracket comprises a bottom plate fixed on the bottom wall, two parallel flanges extending from opposite sides of the bottom plate, and a plurality of pairs of bars extending perpendicularly from the flanges, the slide rails are positioned on top portions of the bars.

6. The electronic device as claimed in claim 5, wherein a motherboard is supported on the bottom wall adjacent to the fan module, a plurality of connectors is arranged on the bottom plate and electrically connected to the motherboard, each fan comprises a fan connector inserted in a corresponding one of the connectors.

7. The electronic device as claimed in claim 6, wherein a power unit arranged on a second side of the bottom wall opposite to the sidewall, the cover is located between the sidewall and the power unit and above the motherboard.

8. The electronic device as claimed in claim 6, wherein a function module area is arranged on the bottom wall opposite to the motherboard, the fan module is set on the bottom wall between the motherboard and the function module area.

9. An electronic device, comprising:
a chassis comprising a bottom wall and a cover spaced from the bottom wall;
a bracket mounted on the bottom wall and receiving a fan; and
a blocking plate slidably mounted on a top portion of the bracket and exposed out of the cover, wherein the blocking plate is operable of covering or uncovering the fan.

10. The electronic device as claimed in claim 9, wherein two slide rails are mounted on a top portion of the bracket, the blocking plate is slidably mounted between the slide rails.

11. The electronic device as claimed in claim 9, wherein a slide slot is defined in each slide rail facing the other slide rail, the blocking plate comprises two edges respectively received in the slide slots.

12. The electronic device as claimed in claim 9, wherein an operation portion extends from a top of the blocking plate.

13. The electronic device as claimed in claim 9, wherein the bracket comprises a bottom plate fixed on the bottom wall, two parallel flanges extending from opposite sides of the bottom plate, and four bars extending perpendicularly from the flanges, the slide rails are positioned on top portions of the bars.

14. The electronic device as claimed in claim 13, wherein a motherboard is supported on the bottom wall adjacent to the fan module, a connector is arranged on the bottom plate and electrically connected to the motherboard, the fan comprises a fan connector inserted in the connector.

15. The electronic device as claimed in claim 14, wherein a sidewall extends from a first side of the bottom wall, a power unit arranged on a second side of the bottom wall opposite to the sidewall, the cover is located between the sidewall and the power unit.

16. The electronic device as claimed in claim 14, wherein a function module area is arranged on the bottom wall opposite to the motherboard, the fan module is set on the bottom wall between the motherboard and the function module area.
